(19) United States
(12) Patent Application Publication
(10) Pub. No.: US 2009/0065795 A1
(43) Pub. Date: Mar. 12, 2009

(54) TRANSPARENT CONDUCTIVE FILM ON P-TYPE LAYER FOR GAN-BASED LED AND METHOD FOR FABRICATING THE SAME

(76) Inventors: Philip Chan, Guangzhou (CN); Raymond Wang, Guangzhou (CN); Leo Lei, Guangzhou (CN)

Correspondence Address: RADER, FISHMAN & GRAUER PLLC, 39533 WOODWARD AVENUE, SUITE 140, BLOOMFIELD HILLS, MI, 48304-0610, US

(21) Appl. No.: 12/184,179

(22) Filed: Jul. 31, 2008

(30) Foreign Application Priority Data
Sep. 12, 2007 (CN) 200710121708.2

(51) Int. Cl. H01L 33/00; H01L 21/00

(52) U.S. Cl. 257/99; 257/103; 438/29; 257/E33.058

(57) ABSTRACT

The present disclosure provides a transparent conductive film on P-type layer of GaN-based LED and a fabricating method thereof. The transparent conductive film is fabricated by Ni/ITO, Al/ITO or NiO/ITO. In one embodiment, the thickness of the Ni layer is 5 Å to 30 Å. The thickness of the Al layer is 5 Å to 30 Å. The thickness of the NiO layer is 5 Å to 40 Å. The thickness of the ITO layer is 1000 Å to 3000 Å. In one embodiment, the fabricating method comprises steps of evaporating one of Ni, Al and NiO layers on a P-type GaN layer, heat-treating a wafer on which the Ni or Al layer is evaporated, then evaporating an ITO layer on the surface of Ni, Al or NiO layer, and heat-treating the wafer on which Ni/ITO, Al/ITO or NiO/ITO layers are evaporated. The transparent conductive film can have high light transmittance within the range of visible light and low specific contact resistance.

### CROSS-REFERENCE TO RELATED APPLICATIONS

This application claims priority from Chinese Patent Application Serial No. 200710121708.2 filed Sep. 12, 2007, the disclosure of which, including the specification, drawings and claims, is incorporated herein by reference in its entirety.

### TECHNICAL FIELD

The present disclosure relates to light emitting diodes (LED), and more specifically to a transparent conductive film on a P-type layer of GaN-based LED and the fabricating method thereof.

### BACKGROUND

The GaN (Gallium Nitride) material is suitably used as an element of blue or green luminescent materials because it has a wide band gap (about 3.4 eV at normal temperature) and also a direct band gap.

During epitaxy in Metal Organic Chemical Vapor Deposition (MOCVD), H atom and Mg form a composite center, wherein the H atom is released by NH₃. The deep energy level which the composite center belongs to draws away a majority of holes to cause a semi-insulating property of the semiconductor. Moreover, during the activation process of thermal annealing, only one percent of Mg-doped is activated. Therefore, for attaining much lower contact resistance, much higher concentration of holes is necessary. For this reason, the property of blue-light GaN-based LED currently shows it is difficult for carriers to diffuse, thus resulting in current crowding effect. Moreover, using metal electrode makes a majority of light compositely produced by luminescent layer be covered by electrode. Thus the luminous efficiency is significantly reduced, and the working life of components is shortened.

To solve this problem, it is necessary to replace the traditional metal electrode with a transparent electrode to cause the current to be distributed uniformly so as to increase a luminescent effect of the active layer. However, the materials for transparent electrode should meet three requirements: 1) low specific contact resistance, to reduce the working voltage of GaN-based LED; 2) high light transmittance, to make the light emitted by the active layer penetrate effectively and avoid being absorbed and reflected; and 3) low resistivity of the electrode itself, to make the current be distributed uniformly. Because work function of P-type GaN is as much as 7.5 eV, general metal work functions can't meet the requirements of ohmic contact with P-type GaN. Since the work function of high work function metal Ni is 5.15 eV, the metal film of Ni—Au alloy was chosen to be used as transparent conducting film earlier on, and the resistivity can be 1×10⁻⁵ Ω·cm when metal film of Ni is used as transparent electrode. Nevertheless the metal film must be fabricated very thin to increase its penetration rate within the range of visible light. However, when the metal film is rather thin (about 100 Å), it is easy to form island-shaped discontinuous film to cause the film resistance to be increased. When the island-shaped discontinuous film further becomes larger, the penetration rate will be decreased because of scattering effect. The light transmittance of the Ni—Au alloy metal film is only between 65% and 75%. However, the light transmittance is relatively high in the visible light region when ITO is used as metal oxide semiconductor film, whereas the resistivity is rather high, being 1×10⁻⁴ Ω·cm.

### SUMMARY

The present disclosure provides a transparent conductive film on P-type layer of GaN-based LED and a fabricating method thereof so as to make the transparent conducting film not only achieve high light transmittance within the range of visible light but also achieve low specific contact resistance, therefore reduce the working voltage of GaN-based LED, and extend the working life of components.

To achieve the above goal, in one embodiment there is provided a transparent conductive film on a P-type layer of GaN-based LED, wherein the transparent conductive film is fabricated by Ni/Indium Tin Oxide (ITO), Al/ITO or NiO/ITO; the first layer of the transparent conductive film evaporated on the P-type layer is one of Ni, Al and NiO, and the second layer is ITO; the thickness of the Ni layer is equal to or thicker than 5 Å and equal to or thinner than 30 Å, the thickness of the Al layer is equal to or thicker than 5 Å and equal to or thinner 30 Å, and the thickness of the NiO layer is equal to or thicker than 5 Å and equal to or thinner than 40 Å, and the thickness of the ITO layer is equal to or thicker than 1000 Å and equal to or thinner than 3000 Å.

There is also provided a method for fabricating the above-mentioned transparent conductive film on P-type layer of GaN-based LED, comprising the following steps:
(1) epitaxially growing an N-type GaN layer, an active luminescent layer, and a P-type GaN layer on a sapphire substrate in turn;
(2) etching said layers into a step with an appropriate depth to expose the N-type GaN layer;
(3) evaporating a Ni layer or Al layer on the P-type GaN layer under the condition that the vacuum degree is less than 1×10⁻⁶ Torr;
(4) heat-treating the wafer on which the Ni or Al layers is evaporated under the condition that the ratio of the flow rate of oxygen to that of nitrogen is 1:4 and the temperature is equal to or higher than 400 degrees and equal to or lower than 550 degrees, and the time for heat treatment is equal to or longer than 10 minutes and equal to or shorter than 25 minutes;
(5) evaporating an ITO layer on the surface of the Ni or Al layer under the condition that the vacuum degree is less than 1×10⁶ Torr; and
(6) heat-treating a wafer on which Ni/ITO or Al/ITO layers are evaporated under the condition that the flow rate of nitrogen is equal to or greater than 5 sccm and equal to or less than 30 sccm, the temperature is equal to or higher than 500 degrees and equal to or lower than 700 degrees, and the time for heat treatment is equal to or longer than 10 minutes and equal to or shorter than 25 minutes.

There is also provided another method for fabricating the above-mentioned transparent conductive film on a P-type layer of GaN-based LED, comprising the following steps:
(1) epitaxially growing an N-type GaN layer, an active luminescent layer, and a P-type GaN layer on a sapphire substrate in turn;
(2) etching said layers into a step with an appropriate depth to expose the N-type GaN layer;
(3) evaporating a NiO layer on the P-type GaN layer under the condition that the vacuum degree is less than 1×10⁻⁶ Torr;
(4) evaporating an ITO layer on the surface of the NiO layer under the condition that the vacuum degree is less than 1×10⁻⁶ Torr; and
(5) heat-treating the wafer on which NiO/ITO layers are evaporated under the condition that the flow rate of nitrogen is equal to or greater than 5 sccm and equal to or less than 30 sccm, the temperature is equal to or higher than 500 degrees and equal to or lower than 700 degrees, and the time for heat treatment is equal to or longer than 10 minutes and equal or shorter than 25 minutes.

According to the present disclosure, the transparent conductive film on P-type layer of GaN-based LED is fabricated by adopting one combination chosen from Ni/ITO, Al/ITO and NiO/ITO, choosing appropriate doping and controlling oxidation state of film. Compared with the transparent conductive film fabricated by metal film of Ni—Au alloy, the transparent conductive film according to the present disclosure can achieve high light transmittance, thus increasing external luminous efficiency. Compared with the transparent conductive film fabricated by metal oxide semiconductor film of ITO, the transparent conductive film on P-type layer of GaN-based LED according to the present disclosure can achieve low specific contact resistance and good ohmic contact since Ni, Al or NiO with high work function can more effectively diffuse to the surface of P-type GaN, and then can reduce the working voltage of GaN-based LED and extend the working life of components.

### BRIEF DESCRIPTION OF THE DRAWINGS

The accompanying drawings, which are incorporated in and constitute a part of specification, illustrate an exemplary embodiment of the present invention and, together with the general description given above and the detailed description of the preferred embodiment given below, serve to explain the principles of the present invention.

FIG. 1 is a flow chat showing one embodiment of a method for fabricating transparent conductive film on P-type layer of GaN-based LED according the present disclosure;

FIG. 2 is a flow chat showing another embodiment of a method for fabricating transparent conductive film on P-type layer of GaN-based LED according to the present disclosure;

FIG. 3 is a schematic sectional view of the epitaxial structure of GaN-based LED chip on a sapphire substrate according to the present disclosure;

FIG. 4 is a schematic sectional view of etching out part of N-type layer on the epitaxial structure of GaN-based LED chip according to the present disclosure;

FIG. 5 is a schematic sectional view of transparent conductive film on P-type layer of GaN-based LED chip using Ni/ITO according to the present disclosure;

FIG. 6 is a schematic sectional view of transparent conductive film on P-type layer of GaN-based LED chip using Al/ITO according to the present disclosure;

FIG. 7 is a schematic sectional view of transparent conductive film on P-type layer of GaN-based LED chip using NiO/ITO according to the present disclosure.

### DETAILED DESCRIPTION

While the claims are not limited to the illustrated embodiments, an appreciation of various aspects of the present invention is best gained through a discussion of various examples thereof. Referring now to the drawings, illustrative embodiments will be described in detail. Although the drawings represent the embodiments, the drawings are not necessarily to scale and certain features may be exaggerated to better illustrate and explain an innovative aspect of an embodiment. Further, the embodiments described herein are not intended to be exhaustive or otherwise limiting or restricting to the precise form and configuration shown in the drawings and disclosed in the following detailed description.

### First Embodiment

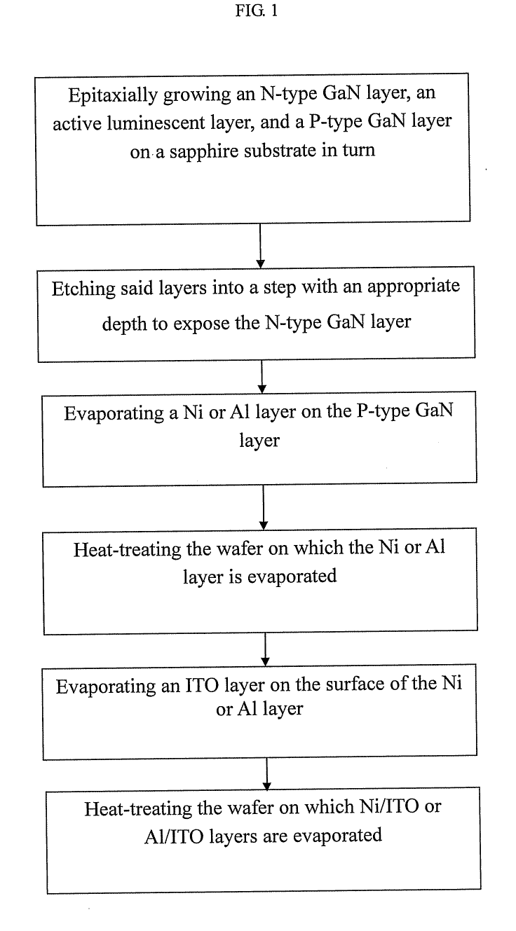

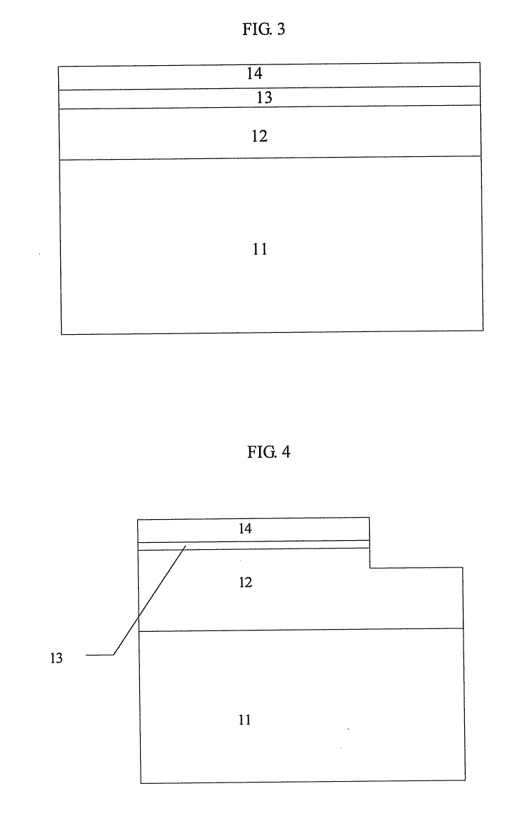

With reference to FIG. 1, a method for fabricating a transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using metal organic chemical vapor deposition (MOCVD) equipment, as shown in FIG. 3;
(2) etching said layers into a step with an appropriate depth to expose the N-type GaN layer 12 with the method of inductively coupled plasma dry etch, as shown in FIG. 4;
(3) evaporating a Ni layer 15 5 Å thick on the P-type GaN layer 14 by using an E-Beam & Thermal (Electron Beam Evaporator) at the vacuum degree of 9.99×10⁻⁷ Torr, as shown in FIG. 5;
(4) heat-treating the wafer for 10 minutes on which the Ni layer 15 is evaporated at the temperature of 400 degrees in an alloy furnace wherein 1 sccm of oxygen and 4 sccm of nitrogen are introduced;
(5) evaporating an ITO layer 18 1000 Å thick on the surface of the Ni layer 15 by using an ITO evaporation machine at the vacuum degree of 9.99×10⁻⁷ Torr, as shown in FIG. 5; and
(6) heat-treating the wafer for 10 minutes on which the Ni layer 15 and the ITO layer 18 are evaporated at the temperature of 500 degrees in the alloy furnace wherein 5 sccm nitrogen is introduced.

The specific contact resistance of the transparent conductive film on the P-type layer of GaN-based LED fabricated by Ni/ITO according to the above method is 4.08×10⁻⁵ Ω·cm, and its light transmittance is 88.2%.

### Second embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a Ni layer 15 10 Å thick on the P-type GaN layer 14 by using an E-Beam & Thermal (Electron Beam Evaporator) at the vacuum degree of 9.99×10⁻⁷ Torr;
(4) heat-treating the wafer for 15 minutes on which the Ni layer 15 is evaporated at the temperature of 450 degrees in the alloy furnace wherein 2 sccm oxygen and 8 sccm nitrogen are introduced;
(5) evaporating an ITO layer 18 2400 Å thick on the surface of the Ni layer 15 by using ITO evaporation machine at the vacuum degree of 9.99×10⁻⁷ Torr; and
(6) heat-treating the wafer for 15 minutes on which the Ni layer 15 and the ITO layer 18 are evaporated at the temperature of 550 degrees in the alloy furnace wherein 10 sccm nitrogen is introduced.

The specific contact resistance of the transparent conductive film on the P-type layer of GaN-based LED fabricated by Ni/ITO according to the above method is 4.22×10⁻⁵ Ω·cm, and its light transmittance is 93.2%.

### Third Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a Ni layer 15 12 Å thick on the P-type GaN layer 14 by using an E-Beam & Thermal(Electron Beam Evaporator) at the vacuum degree of 9.99×10⁻⁷ Torr;
(4) heat-treating the wafer for 15 minutes on which the Ni layer 15 is evaporated at the temperature of 475 □ in the alloy furnace wherein 3 sccm oxygen and 12 sccm nitrogen are introduced;
(5) evaporating an ITO layer 18 2550 Å thick on the surface of the Ni layer 15 by using an ITO evaporation machine at the vacuum degree of 9.99×10⁻⁷ Torr; and
(6) heat-treating the wafer for 15 minutes on which the Ni layer 15 and the ITO layer 18 are evaporated at the temperature of 575 □ in the alloy furnace wherein 15 sccm nitrogen is introduced.

The specific contact resistance of the transparent conductive film on the P-type layer of GaN-based LED fabricated by Ni/ITO according to the above method is 4.57×10⁻⁵ Ω·cm, and its light transmittance is 96.8%.

### Fourth Embodiment

A method for fabricating the transparent conductive film on P-type layer of GaN-based LED according to the present disclosure generally comprises the following steps:
(1) epitaxially growing an N-type GaN layer 12, an active luminescent layer 13, a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a Ni layer 15 15 Å thick on the P-type GaN layer 14 by using an E-Beam & Thermal(Electron Beam Evaporator) at the vacuum degree of 9.99×10⁻⁷ Torr;
(4) heat-treating the wafer for 15 minutes on which the Ni layer 15 is evaporated at the temperature of 500 degrees in the alloy furnace wherein 4 sccm oxygen and 16 sccm nitrogen are introduced;
(5) evaporating an ITO layer 18 2700 Å thick on the surface of the Ni layer 15 by using an ITO evaporation machine at the vacuum degree of 9.99×10⁻⁷ Torr; and
(6) heat-treating the wafer for 15 minutes on which the Ni layer 15 and the ITO layer 18 are evaporated at the temperature of 600 degrees in the alloy furnace wherein 20 sccm nitrogen is introduced.

The specific contact resistance of the transparent conductive film on the P-type layer of GaN-based LED fabricated by Ni/ITO according to the above method is 4.43×10⁻⁵ Ω·cm, and its light transmittance is 95.2%.

### Fifth Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a Ni layer 15 30 Å thick on the P-type GaN layer 14 by using an E-Beam & Thermal(Electron Beam Evaporator) at the vacuum degree of 9.99×10⁻⁷ Torr;
(4) heat-treating the wafer for 25 minutes on which the Ni layer 15 is evaporated at the temperature of 550 degrees in the alloy furnace wherein 5 sccm oxygen and 20 sccm nitrogen are introduced;
(5) evaporating an ITO layer 18 3000 Å thick on the surface of the Ni layer 15 by using an ITO evaporation machine at the vacuum degree of 9.99×10⁻⁷ Torr; and
(6) heat-treating the wafer for 15 minutes on which the Ni layer 15 and the ITO layer 18 are evaporated at the temperature of 700 degrees in the alloy furnace wherein 30 sccm nitrogen is introduced.

The specific contact resistance of the transparent conductive film on the P-type layer of GaN-based LED fabricated by Ni/ITO according to the above method is 4.13×10⁻⁵ Ω·cm, and its light transmittance is 89.6%.

### Sixth Embodiment

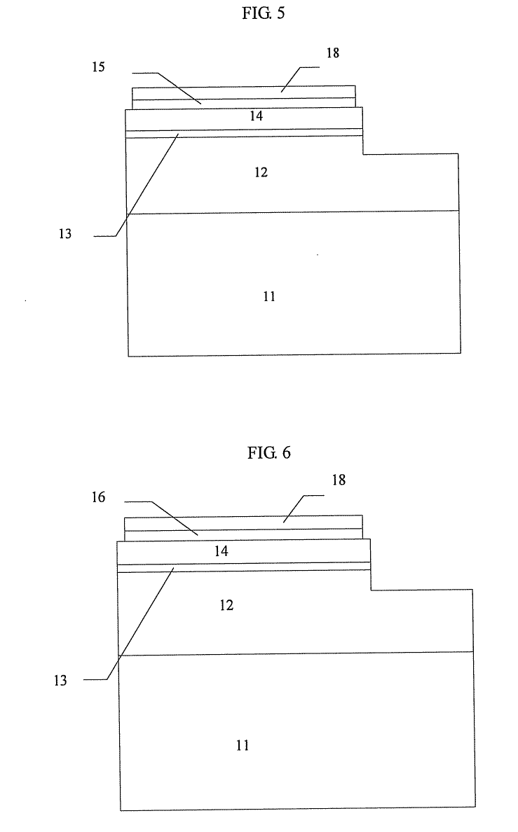

With reference to FIG. 1, a method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment, as shown in FIG. 3;
(2) etching said layers into a step with an appropriate depth to expose the N-type GaN layer 12 with the method of inductively coupled plasma dry etch, as shown in FIG. 4;
(3) evaporating an Al layer 16 5 Å thick on the P-type GaN layer 14 by using an E-Beam & Thermal (Electron Beam Evaporator) at the vacuum degree of 9.99×10⁻⁷ Torr, as shown in FIG. 6;
(4) heat-treating the wafer for 10 minutes on which the Al layer 16 is evaporated at the temperature of 400 degrees in the alloy furnace wherein 1 sccm oxygen and 4 sccm nitrogen are introduced;
(5) evaporating an ITO layer 18 1000 Å thick on the surface of the Al layer 16 by using an ITO evaporation machine at the vacuum degree of 9.99×10⁻⁷ Torr, as shown in FIG. 6;
(6) heat-treating the wafer for 10 minutes on which the Al layer 16 and the ITO layer 18 are evaporated at the temperature of 500 degrees in the alloy furnace wherein 5 sccm nitrogen is introduced.

The specific contact resistance of the transparent conductive film on the P-type layer of GaN-based LED fabricated by Al/ITO according to the above method is 4.11×10⁻⁵ Ω·cm, and its light transmittance is 89.4%.

### Seventh Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating an Al 16 10 Å thick on the P-type GaN layer 14 by using an E-Beam & Thermal (Electron Beam Evaporator) at the vacuum degree of 9.99×10⁻⁷ Torr;
(4) heat-treating the wafer for 15 minutes on which the Al layer 16 is evaporated at the temperature of 450 degrees in the alloy furnace wherein 2 sccm oxygen and 8 sccm nitrogen are introduced;
(5) evaporating an ITO layer 18 2400 Å thick on the surface of the Al layer 16 by using an ITO evaporation machine at the vacuum degree of 9.99×10⁻⁷ Torr;
(6) heat-treating the wafer for 15 minutes on which the Al layer 16 and the ITO layer 18 are evaporated at the temperature of 550 degrees in the alloy furnace wherein 10 sccm nitrogen is introduced.

The specific contact resistance of the transparent conductive film on the P-type layer of GaN-based LED is fabricated by Al/ITO according to the above method is 4.31×10⁵ Ω·cm, and its light transmittance is 93.6%.

### Eighth Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating an Al layer 16 12 Å thick on the P-type GaN layer 14 by using an E-Beam & Thermal (Electron Beam Evaporator) at the vacuum degree of 9.99×10⁻⁷ Torr;
(4) heat-treating the wafer for 15 minutes on which the Al layer 16 is evaporated at the temperature of 475 degrees in the alloy furnace wherein 3 sccm oxygen and 12 sccm nitrogen are introduced;
(5) evaporating an ITO layer 18 2550 Å thick on the surface of the Al layer 16 by using an ITO evaporation machine at the vacuum degree of 9.99×10⁻⁷ Torr;
(6) heat-treating the wafer for 15 minutes on which the Al layer 16 and the ITO layer 18 are evaporated at the temperature of 575 degrees in the alloy furnace wherein 15 sccm nitrogen is introduced.

The specific contact resistance of the transparent conductive film on the P-type layer of GaN-based LED fabricated by Al/ITO according to the above method is 4.47×10⁻⁵ Ω·cm, and its light transmittance is 94.9%.

### Ninth Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating an Al layer 16 15 Å thick on the P-type GaN layer 14 by using an E-Beam & Thermal(Electron Beam Evaporator) at the vacuum degree of 9.99×10⁻⁷ Torr;
(4) heat-treating the wafer for 15 minutes on which the Al layer 16 is evaporated at the temperature of 500 degrees in the alloy furnace wherein 4 sccm oxygen and 16 sccm nitrogen are introduced;
(5) evaporating an ITO layer 18 2700 Å thick on the surface of the Al layer 16 by using an ITO evaporation machine at the vacuum degree of 9.99×10⁻⁷ Torr;
(6) heat-treating the wafer for 15 minutes on which the Al layer 16 and the ITO layer 18 are evaporated at the temperature of 600 degrees in the alloy furnace wherein 20 sccm nitrogen is introduced.

The specific contact resistance of the transparent conductive film on the P-type layer of GaN-based LED fabricated by Al/ITO according to the above method is 4.41×10⁻⁵ Ω·cm, and its light transmittance is 95.8%.

### Tenth Embodiment

A method for fabricating the transparent conductive film on P-type layer of GaN-based LED according to the present invention generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating an Al layer 16 30 Å thick on the P-type GaN layer 14 by using an E-Beam & Thermal(Electron Beam Evaporator) at the vacuum degree of 9.99×10⁻⁷ Torr;
(4) heat-treating the wafer for 25 minutes on which the Al layer 16 is evaporated at the temperature of 550 degrees in the alloy furnace wherein 5 sccm oxygen and 20 sccm nitrogen are introduced;
(5) evaporating an ITO layer 18 3000 Å thick on the surface of the Al layer 16 by using an ITO evaporation machine at the vacuum degree of 9.99×10⁻⁷ Torr;
(6) heat-treating the wafer for 25 minutes on which the Al layer 16 and the ITO layer 18 are evaporated at the temperature of 700 degrees in the alloy furnace wherein 30 sccm nitrogen is introduced.

The specific contact resistance of the transparent conductive film on the P-type layer of GaN-based LED fabricated by Al/ITO according to the above method is 4.15×10⁻⁵ Ω·cm, and its light transmittance is 89.5%.

### Eleventh Embodiment

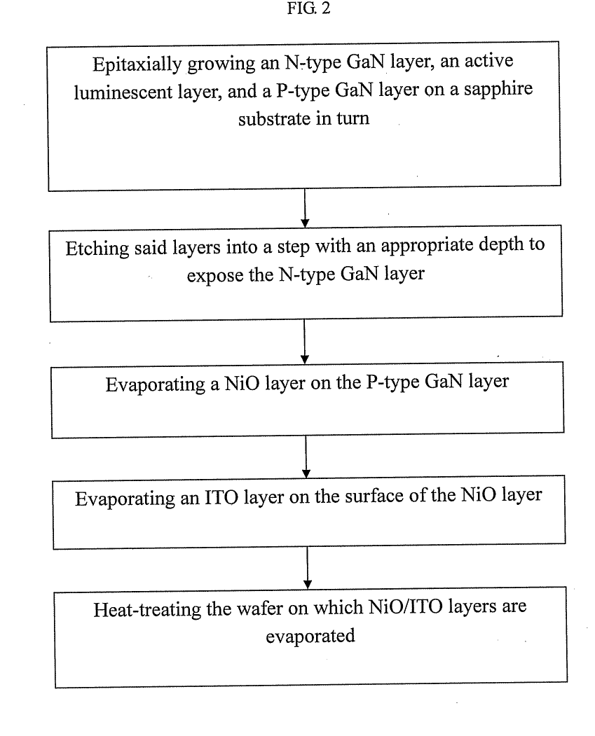

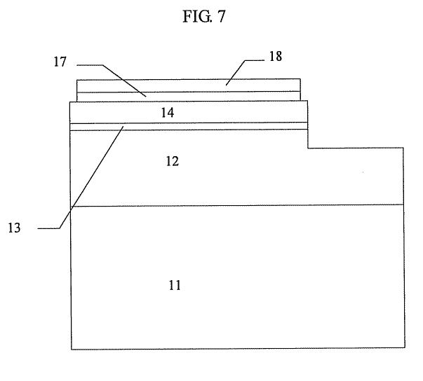

With reference to FIG. 2, a method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment, as shown in FIG. 3;
(2) etching said layers into a step with an appropriate depth to expose the N-type GaN layer 12 with the method of inductively coupled plasma dry etch, as shown in FIG. 4;
(3) evaporating a NiO layer 17 5 Å thick on the P-type GaN layer 14 by using an E-Beam & Thermal(Electron Beam Evaporator) at the vacuum degree of 9.99×10⁻⁷ Torr, as shown in FIG. 7;
(4) evaporating an ITO layer 18 1000 Å thick on the surface of the NiO layer 17 by using an ITO evaporation machine at the vacuum degree of 9.99×10⁻⁷ Torr, as shown in FIG. 7;
(5) heat-treating the wafer for 10 minutes on which the NiO layer 17 and the ITO layer 18 are evaporated at the temperature of 500 degrees in the alloy furnace wherein 5 sccm nitrogen is introduced.

The specific contact resistance of the transparent conductive film on the P-type layer of GaN-based LED fabricated by NiO/ITO according to the above method is 4.09×10⁻⁵ Ω·cm, and its light transmittance is 90.2%.

### Twelfth Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a NiO layer 17 10 Å thick on the P-type GaN layer 14 by using an E-Beam & Thermal(Electron Beam Evaporator) at the vacuum degree of 9.99×10⁻⁷ Torr;
(4) evaporating an ITO layer 18 2400 Å thick on the surface of the NiO layer 17 by using an ITO evaporation machine at the vacuum degree of
(5) heat-treating the wafer for 15 minutes on which the NiO layer 17 and the ITO layer 18 are evaporated at the temperature of 550 degrees in the alloy furnace wherein 10 sccm nitrogen is introduced.

The specific contact resistance of the transparent conductive film on the P-type layer of GaN-based LED fabricated by NiO/ITO according to the above method is 4.38×10⁻⁵ Ω·cm, and its light transmittance is 94.6%.

### Thirteenth Embodiment

A method for fabricating the transparent conductive film on P-type layer of GaN-based LED according to the present invention generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a NiO layer 17 15 Å thick on the P-type GaN layer 14 by using an E-Beam & Thermal(Electron Beam Evaporator) at the vacuum degree of 9.99×10⁻⁷ Torr;
(4) evaporating an ITO layer 18 2550 Å thick on the surface of the NiO layer 17 by using ITO evaporation machine at the vacuum degree of 9.99×10⁻⁷ Torr;
(5) heat-treating the wafer for 15 minutes on which the NiO layer 17 and the ITO layer 18 are evaporated at the temperature of 575 degrees in the alloy furnace wherein 15 sccm nitrogen is introduced.

The specific contact resistance of the transparent conductive film on the P-type layer of the GaN-based LED fabricated by NiO/ITO according to the above method is 4.67×10⁻⁵ Ω·cm, and its light transmittance is 97.3%.

### Fourteenth Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a NiO layer 17 20 Å thick on the P-type GaN layer 14 by using an E-Beam & Thermal (Electron Beam Evaporator) at the vacuum degree of 9.99×10⁻⁷ Torr;
(4) evaporating an ITO layer 18 2700 Å thick on the surface of the NiO layer 17 by using ITO evaporation machine at the vacuum degree of 9.99×10⁻⁷ Torr;
(5) heat-treating the wafer for 15 minutes on which the NiO 17 layer and the ITO layer 18 are evaporated at the temperature of 600 degrees in the alloy furnace wherein 20 sccm nitrogen is introduced.

The specific contact resistance of the transparent conductive film on the P-type layer of the GaN-based LED fabricated by NiO/ITO according to the above method is 4.68×10⁻⁵ Ω·cm, and its light transmittance is 96.3%.

### Fifteenth Embodiment

A method for fabricating the transparent conductive film on P-type layer of GaN-based LED according to the present disclosure generally comprises the following steps:
(1) epitaxially growing an N-type GaN layer 12, an active luminescent layer 13, and a P-type GaN layer 14 on a sapphire substrate 11 in turn by using MOCVD equipment;
(2) etching said layers into a step with an appropriate depth to expose the N-type GaN layer 12 with the method of inductively coupled plasma dry etch;
(3) evaporating a NiO layer 17 30 Å thick on the P-type GaN layer 14 by using an E-Beam & Thermal(Electron Beam Evaporator) at the vacuum degree of 9.99×10⁻⁷ Torr;
(4) evaporating an ITO layer 18 3000 Å thick on the surface of the NiO layer 17 by using ITO evaporation machine at the vacuum degree of 9.99×10⁻⁷ Torr;
(5) heat-treating the wafer for 25 minutes on which the NiO layer 17 and the ITO layer 18 are evaporated at the temperature of 700 degrees in the alloy furnace wherein 30 sccm nitrogen is introduced.

The specific contact resistance of the transparent conductive film on the P-type layer of the GaN-based LED fabricated by NiO/ITO according to the above method is 4.20×10⁻⁵ Ω·cm, and its light transmittance is 91.5%.

The foregoing description of various embodiments of the invention has been present for purpose of illustration and description. It is not intent to be exhaustive or to limit the invention to the precise embodiments disclosed. Numerous modifications or variations are possible in light of the above teachings. The embodiments discussed where chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A transparent conductive film on P-type layer of GaN-based light emitting diode (LED), wherein the transparent conductive film is fabricated by Ni/Indium Tin Oxide (ITO), Al/ITO or NiO/ITO; comprising a first layer of the transparent conductive film evaporated on the P-type layer, which is one of Ni, Al and NiO, and a second layer, which is ITO; wherein the thickness of the Ni layer is equal to or thicker than 5 Å and equal to or thinner than 30 Å, the thickness of the Al layer is equal to or thicker than 5 Å and equal to or thinner than 30 Å, and the thickness of the NiO layer is equal to or thicker than 5 Å and equal to or thinner than 40 Å, and the thickness of the ITO layer is equal to or thicker than 1000 Å and equal to or thinner than 3000 Å.

2. The transparent conductive film on P-type layer of GaN-based LED as claimed in claim 1, wherein the thickness of the Ni layer is equal to or thicker than 10 Å and equal to or thinner than 15 Å; the thickness of the Al layer is equal to or thicker than 10 Å and equal to or thinner than 15 Å; the thickness of the NiO layer is equal to or thicker than 10 Å and equal to or thinner than 20 Å; and the thickness of the ITO layer is equal to or thicker than 2400 Å and equal to or thinner than 2700 Å.

3. A method for fabricating a transparent conductive film on P-type layer of GaN-based LED comprising:
(1) epitaxially growing an N-type GaN layer, an active luminescent layer, and a P-type GaN layer on a sapphire substrate in turn;
(2) etching said layers into a step with an appropriate depth to expose the N-type GaN layer;
(3) evaporating a Ni layer or Al layer on the P-type GaN layer under a condition such that the vacuum degree is less than 1×10^{31 6} Torr;
(4) heat-treating a wafer on which Ni or Al layer is evaporated under the condition that a ratio of a flow rate of oxygen to that of nitrogen is 1:4 and the temperature is equal to or higher than 400 degrees and equal to or lower than 550 degrees, and the time for heat treatment is equal to or longer than 10 minutes and equal to or shorter than 25 minutes;
(5) evaporating an ITO layer on a surface of the Ni or Al layer under the condition that the vacuum degree is less than 1×10⁻⁶ Torr; and
(6) heat-treating the wafer on which the Ni/ITO or Al/ITO layers are evaporated under the condition that a flow rate of nitrogen is equal to or greater than 5 sccm and equal to or less than 30 sccm, the temperature is equal to or higher than 500 degrees and equal to or lower than 700 degrees, and the time for heat treatment is equal to or longer than 10 minutes and equal to or shorter than 25 minutes.

4. The method for fabricating the transparent conductive film on P-type layer of GaN-based LED as claimed in claim 3, wherein the temperature in step (4) is equal to or higher than 450 degrees and equal to or lower than 500 degrees.

5. The method for fabricating the transparent conductive film on P-type layer of GaN-based LED as claimed in claim 3, wherein the flow rate of nitrogen in the step (6) is equal to or greater than 10 sccm and equal to or less than 20 sccm.

6. The method for fabricating the transparent conductive film on P-type layer of GaN-based LED as claimed in claim 3, wherein the temperature in the step (6) is equal to or higher than 550 degrees and equal to or lower than 600 degrees.

7. A method for fabricating a transparent conductive film on P-type layer of GaN-based LED comprising:
(1) epitaxially growing an N-type GaN layer, an active luminescent layer, and a P-type GaN layer on a sapphire substrate in turn;
(2) etching said layers into a step with an appropriate depth to expose the N-type GaN layer;
(3) evaporating a NiO layer on the P-type GaN layer under the condition that the vacuum degree is less than 1×10⁻⁶ Torr;
(4) evaporating an ITO layer on a surface of the NiO layer under the condition that the vacuum degree is less than 1×10⁻⁶ Torr; and
(5) heat-treating a wafer on which NiO/ITO layers are evaporated under the condition that the flow rate of nitrogen is equal to or greater than 5 sccm and equal to or less than 30 sccm, the temperature is equal to or higher than 500 degrees and equal to or lower than 700 degrees, and the time for heat treatment is equal to or longer than 10 minutes and equal to or shorter than 25 minutes.

8. The method for fabricating the transparent conductive film on P-type layer of GaN-based LED as claimed in claim 7, wherein a flow rate of nitrogen in the step(5) is equal to or greater than 10 sccm and equal to or less than 20 sccm.

9. The method for fabricating the transparent conductive film on P-type layer of GaN-based LED as claimed in claim 7, wherein the temperature in the step (5) is equal to or higher than 550 degrees and equal to or lower than 600 degrees.
